(19) United States
(12) Patent Application Publication
(10) Pub. No.: US 2017/0140917 A1
(43) Pub. Date: May 18, 2017

(54) MANUFACTURING APPARATUS FOR SEMICONDUCTOR DEVICE AND METHOD OF MANUFACTURING SEMICONDUCTOR DEVICE

(71) Applicant: TOYOTA JIDOSHA KABUSHIKI KAISHA, Toyota-shi (JP)

(72) Inventor: Taichi YOSHIDA, Iwakura-shi (JP)

(73) Assignee: TOYOTA JIDOSHA KABUSHIKI KAISHA, Toyota-shi (JP)

(21) Appl. No.: 15/338,564

(22) Filed: Oct. 31, 2016

(30) Foreign Application Priority Data
Nov. 18, 2015 (JP) 2015-225594

(51) Int. Cl. H01L 21/02; H01L 21/687; B08B 3/04; H01L 21/67

(52) U.S. Cl. CPC H01L 21/0209; H01L 21/67051; H01L 21/68785; B08B 3/04; H01L 21/02282; H01L 21/0206

(57) ABSTRACT

An adhesion liquid is supplied onto a front side of a wafer having a disk-shape while a rinse liquid is discharged onto a backside of the wafer that is rotating. The rinse liquid is discharged to a position close to a rotational center of the wafer and a position close to an outer peripheral edge of the wafer. The rinse liquid reaches an outer peripheral end surface of the wafer, and thus adhesion of the adhesion liquid to the outer peripheral end surface is reduced.

### INCORPORATION BY REFERENCE

The disclosure of Japanese Patent Application No. 2015-225594 filed on Nov. 18, 2015 including the specification, drawings and abstract is incorporated herein by reference in its entirety.

### BACKGROUND

1. Technical Field

The disclosure relates to a manufacturing apparatus for a semiconductor device, and relates also to a method of manufacturing a semiconductor device.

2. Description of Related Art

A manufacturing apparatus for a semiconductor device described in Japanese Patent Application Publication No. 2015-076534 (JP 2015-076534 A) includes a rotary holding table, a supply nozzle, and a discharge nozzle. The rotary holding table is configured to rotate a wafer having a disk-shape while holding a central portion of the backside of the wafer. The supply nozzle is configured to supply an adhesion liquid to the front side of the wafer while the wafer is rotating. The adhesion liquid is a liquid to be caused to adhere to the front side of the wafer. The discharge nozzle is configured to discharge a rinse liquid to the backside of the wafer while the wafer is rotating. With this configuration, the adhesion liquid supplied to the front side of the wafer from the supply nozzle is spread toward an outer peripheral edge of the wafer by a centrifugal force due to the rotation of the wafer. In this way, the adhesion liquid adheres to the entirety of the front side of the wafer. In addition, the adhesion liquid spread to the outer peripheral edge of the wafer by the centrifugal force scatters from the outer peripheral edge of the wafer to its surroundings. If no measures are taken, the scattered adhesion liquid may adhere to the backside of the wafer. For example, there is a possibility that the scattered adhesion liquid hits members disposed around the wafer and is then splashed back from the members, and the adhesion liquid splashed back from the members is caught in an airflow on the backside of the wafer and then adheres to the backside of the wafer.

In the manufacturing apparatus of JP 2015-076534 A, the rinse liquid discharged from the discharge nozzle to the backside of the wafer is spread to the outer peripheral edge of the wafer by a centrifugal force due to the rotation of the wafer. In this way, the backside of the wafer can be covered with the rinse liquid, and thus adhesion of the adhesion liquid to the backside of the wafer can be reduced (inhibited). In addition, even when the adhesion liquid adheres to the backside of the wafer, the adhesion liquid can be washed away by the rinse liquid discharged to the backside of the wafer.

### SUMMARY

In the manufacturing apparatus of JP 2015-076534 A, the adhesion liquid supplied to the front side of the wafer and spread to the outer peripheral edge may not only be scattered from the outer peripheral edge of the wafer to its surroundings by the centrifugal force but may also drip from the outer peripheral edge of the wafer and adhere to an outer peripheral end surface of the wafer. In the manufacturing apparatus of JP 2015-076534 A, adhesion of the adhesion liquid to the backside of the wafer can be reduced by the rinse liquid discharged to the backside of the wafer, or the adhesion liquid adhering to the backside of the wafer can be washed away by the rinse liquid. However, it is difficult to reduce adhesion of the adhesion liquid dripping from the outer peripheral edge of the wafer to the outer peripheral end surface of the wafer.

The disclosure provides a technology for reducing adhesion of an adhesion liquid to a backside and an outer peripheral end surface of a wafer.

A first aspect of the disclosure relates to a manufacturing apparatus for a semiconductor device. The manufacturing apparatus includes: a rotary holding table configured to rotate a wafer having a disk-shape while holding a central portion of at least one of a front side and a backside of the wafer; a supply nozzle configured to supply an adhesion liquid onto the front side of the wafer while the wafer is rotating; and at least one discharge nozzle configured to discharge a rinse liquid toward a first position and a second position on the backside of the wafer while the wafer is rotating. The adhesion liquid is a liquid to be caused to adhere to the front side of the wafer. The second position is closer to an outer peripheral edge of the wafer than the first position is in a direction from the outer peripheral edge of the wafer toward a rotational center of the wafer.

With this configuration, the rinse liquid discharged toward the first position is spread from the first position toward the outer peripheral edge by a centrifugal force due to the rotation of the wafer. Further, the rinse liquid discharged toward the second position, which is closer to the outer peripheral edge of the wafer than the first position is, is spread from the second position toward the outer peripheral edge by a centrifugal force due to the rotation of the wafer. The backside of the wafer is covered with the rinse liquid spread from the first position and the second position, and thus adhesion of the adhesion liquid to the backside of the wafer is reduced. In addition, even when the adhesion liquid adheres to the backside of the wafer, the adhesion liquid can be washed away by the rinse liquid discharged to the first position.

The rinse liquid spread to the outer peripheral edge of the wafer by the centrifugal force may be scattered from the outer peripheral edge of the wafer to its surroundings by the centrifugal force. For this reason, in the above configuration, the rinse liquid is discharged to the second position that is closer to the outer peripheral edge of the wafer than the first position is. Because the second position is closer to the outer peripheral edge than the first position is, the time required for the rinse liquid discharged toward the second position to reach the outer peripheral edge is shorter than the time required for the rinse liquid discharged toward the first position to reach the outer peripheral edge. For this reason, the time for which a centrifugal force acts on the rinse liquid discharged toward the second position is shorter than the time for which a centrifugal force acts on the rinse liquid discharged toward the first position. As a result, the flow velocity of the rinse liquid that reaches the outer peripheral edge from the second position is lower than the flow velocity of the rinse liquid that reaches the outer peripheral edge from the first position. Due to such a low flow velocity, the rinse liquid that reaches the outer peripheral edge from the second position is not easily scattered from the outer peripheral edge of the wafer to its surroundings, and is spread from the outer peripheral edge of the wafer to an outer peripheral end surface thereof due to surface tension. As a result, the rinse liquid is spread over the outer peripheral end surface of the wafer, and thus adhesion of the adhesion liquid to the outer peripheral end surface is reduced. In addition, even when the adhesion liquid adheres to the outer peripheral end surface of the wafer, the adhesion liquid can be washed away by the rinse liquid that is spread over the outer peripheral end surface of the wafer. In this way, adhesion of the adhesion liquid to the backside and the outer peripheral end surface of the wafer can be reduced.

A second aspect of the disclosure relates to a method of manufacturing a semiconductor device. The method includes: supplying an adhesion liquid onto a front side of a wafer having a disk-shape while the wafer is rotating; and discharging a rinse liquid toward a first position and a second position on a backside of the wafer while the wafer is rotating. The adhesion liquid is a liquid to be caused to adhere to the front side of the wafer. The second position is closer to an outer peripheral edge of the wafer than the first position is in a direction from the outer peripheral edge of the wafer toward a rotational center of the wafer.

With this configuration, as described above, adhesion of the adhesion liquid to the backside and the outer peripheral end surface of the wafer can be reduced.

### BRIEF DESCRIPTION OF THE DRAWINGS

Features, advantages, and technical and industrial significance of exemplary embodiments will be described below with reference to the accompanying drawings, in which like numerals denote like elements, and wherein:

FIG. 1 is a view schematically illustrating a manufacturing apparatus for a semiconductor device according to a first embodiment; and

FIG. 2 is a view schematically illustrating a manufacturing apparatus for a semiconductor device according to a second embodiment.

### DETAILED DESCRIPTION OF EMBODIMENTS

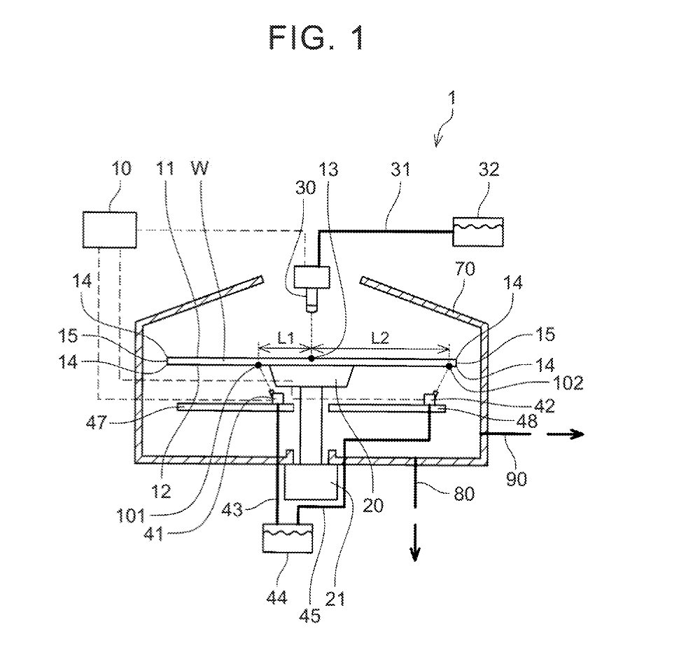

As illustrated in FIG. 1, a manufacturing apparatus 1 according to a first embodiment includes a rotary holding table 20, a rotary driving device 21, a supply nozzle 30, a first discharge nozzle 41, and a second discharge nozzle 42. In addition, the manufacturing apparatus 1 includes a cup 70 and a controller 10. The supply nozzle 30, the first discharge nozzle 41, and the second discharge nozzle 42 are connected to the controller 10. The controller 10 controls the operations of the supply nozzle 30, the first discharge nozzle 41, and the second discharge nozzle 42.

A wafer w having a disk-shape is disposed on the rotary holding table 20. The rotary holding table 20 holds a central portion of a backside 12 of the wafer w. The rotary holding table 20 draws in air, so that the wafer w is suctioned onto the rotary holding table 20. The rotary holding table 20 holds the wafer w with a front side 11 and the backside 12 (except the central portion) of the wafer w exposed. The rotary holding table 20 is rotated through the operation of the rotary driving device 21. The rotary holding table 20 rotates while holding the wafer w. The rotary driving device 21 rotates the rotary holding table 20, using the operation of a motor. The rotary driving device 21 is configured such that the rotational speed and rotation time thereof can be controlled.

The supply nozzle 30 is disposed above the rotary holding table 20. When the wafer w is disposed on the rotary holding table 20, the supply nozzle 30 is disposed above a central portion of the wafer w. The supply nozzle 30 is connected to a supply line 31. The supply line 31 is connected to an adhesion liquid supply source 32. An adhesion liquid is delivered from the adhesion liquid supply source 32 to the supply nozzle 30 through the supply line 31. The supply nozzle 30 supplies the adhesion liquid to the central portion of the wafer w. The supply nozzle 30 supplies the adhesion liquid onto the front side 11 of the wafer w while the wafer w is rotating in accordance with the rotation of the rotary holding table 20. The adhesion liquid supplied onto the front side 11 of the wafer w is spread from the central portion of the wafer w toward an outer peripheral edge 14 of the wafer w by a centrifugal force due to the rotation of the wafer w. The adhesion liquid is a liquid that is caused to adhere to the front side 11 of the wafer w. Examples of the adhesion liquid include a resist liquid. When the adhesion liquid adheres to the front side 11 of the wafer w, a resist film is formed on the front side 11 of the wafer w.

The first discharge nozzle 41 is disposed below the rotary holding table 20. The first discharge nozzle 41 is supported on a first support table 47. The first discharge nozzle 41 is connected to a first supply line 43. The first supply line 43 is connected to a rinse liquid supply source 44. A rinse liquid is delivered from the rinse liquid supply source 44 to the first discharge nozzle 41 through the first supply line 43. The first discharge nozzle 41 discharges the rinse liquid toward an exposed portion of the backside 12 of the wafer w, which is not covered with the rotary holding table 20. The first discharge nozzle 41 discharges the rinse liquid toward the backside 12 of the wafer w while the wafer w is rotating in accordance with the rotation of the rotary holding table 20. The first discharge nozzle 41 discharges the rinse liquid toward a first position 101 on the backside 12 of the wafer w. In the first embodiment, the first position 101 is set to a position on the backside 12 of the wafer w and in the vicinity of a rotational center 13 of the wafer w. The first discharge nozzle 41 discharges the rinse liquid outward in the radial direction of the wafer w and obliquely upward from the wafer w rotational center side. That is, the discharging direction of the rinse liquid (the direction in which the first discharge nozzle 41 discharges the rinse liquid) includes a directional component from the rotational center 13 of the wafer w toward the outer peripheral edge 14 of the wafer w. The rinse liquid discharged onto the backside 12 of the wafer w is spread toward the outer peripheral edge 14 of the backside 12 from the first position 101 on the wafer w by a centrifugal force due to the rotation of the wafer w. The rinse liquid is a liquid for preventing the adhesion liquid from adhering to the wafer w. In addition, the rinse liquid is a liquid capable of washing the adhesion liquid away even when the adhesion liquid adheres to the wafer w. Adhesion of the adhesion liquid (resist liquid) to the backside 12 of the wafer w is reduced (inhibited) by the rinse liquid, and thus formation of the resist film on the backside 12 of the wafer w is reduced by the rinse liquid. In addition, even when the adhesion liquid (resist liquid) adheres to the backside 12 of the wafer w, the adhesion liquid (resist liquid) is washed away by the rinse liquid, so that formation of a resist film on the backside 12 of the wafer w is reduced.

The second discharge nozzle 42 is disposed at a position away from the first discharge nozzle 41. The second discharge nozzle 42 is disposed below the wafer w on the rotary holding table 20. The second discharge nozzle 42 is supported on a second support table 48. The second discharge nozzle 42 is connected to a second supply line 45. The second supply line 45 is connected to the rinse liquid supply source 44. The rinse liquid is delivered to the second discharge nozzle 42 from the rinse liquid supply source 44 through the second supply line 45. The second discharge nozzle 42 discharges the rinse liquid toward an exposed portion of the backside 12 of the wafer w, which is not covered with the rotary holding table 20. The second discharge nozzle 42 discharges the rinse liquid to the backside 12 of the wafer w while the wafer w is rotating in accordance with the rotation of the rotary holding table 20. The second discharge nozzle 42 discharges the rinse liquid toward a second position 102. A distance L2 from the rotational center 13 of the wafer w to the second position 102 is greater than a distance L1 from the rotational center 13 of the wafer w to the first position 101. The second position 102 is a position that is closer to the outer peripheral edge 14 of the wafer w than the first position 101 is (the first position 101 is a position that is closer to the rotational center 13 of the wafer w than the second position 102 is). The second discharge nozzle 42 discharges the rinse liquid outward in the radial direction of the wafer w and obliquely upward from the wafer w rotational center side. The rinse liquid discharged onto the backside 12 of the wafer w is spread from the second position 102 on the wafer w toward the outer peripheral edge 14 by a centrifugal force due to the rotation of the wafer w.

The cup 70 is disposed around the wafer w. The cup 70 surrounds the wafer w. The adhesion liquid and the rinse liquid scattered from the outer peripheral edge 14 of the wafer w to its surroundings by the centrifugal force due to the rotation of the wafer w fall onto a bottom portion of the cup 70. In addition, the scattered adhesion liquid and rinse liquid may hit a side surface of the cup 70. A liquid discharge line 80 is connected to the bottom portion of the cup 70. The adhesion liquid and the rinse liquid are discharged from the bottom portion of the cup 70 to the outside through the liquid discharge line 80. In addition, an intake line 90 is connected to the side surface of the cup 70. The intake line 90 draws in air on the backside of the wafer w. Due to this, the adhesion liquid and the rinse liquid easily fall onto the bottom portion of the cup 70.

In the manufacturing apparatus 1 having the above-described configuration, the controller 10 simultaneously starts the operations of the supply nozzle 30, the first discharge nozzle 41, and the second discharge nozzle 42. Thus, the adhesion liquid is supplied from the supply nozzle 30 onto the front side 11 of the wafer w while the wafer w is rotating, the rinse liquid is discharged from the first discharge nozzle 41 toward the first position 101 on the backside 12 of the wafer w, and the rinse liquid is discharged from the second discharge nozzle 42 toward the second position 102 on the backside 12 of the wafer w.

The adhesion liquid supplied from the supply nozzle 30 onto the front side 11 of the wafer w is spread toward the outer peripheral edge 14 of the front side 11 of the wafer w by a centrifugal force due to the rotation of the wafer w. Thus, the adhesion liquid adheres to the entirety of the front side 11 of the wafer w. In addition, the adhesion liquid spread toward the outer peripheral edge 14 of the wafer w by the centrifugal force is scattered from the outer peripheral edge 14 of the wafer w to its surroundings. In addition, the adhesion liquid drips from the outer peripheral edge 14 of the wafer w.

The rinse liquid discharged toward the first position 101 on the backside 12 of the wafer w from the first discharge nozzle 41 is spread from the first position 101 on the backside 12 toward the outer peripheral edge 14 by a centrifugal force due to the rotation of the wafer w. Further, the rinse liquid discharged toward the second position 102 on the backside 12 of the wafer w from the second discharge nozzle 42 is spread from the second position 102 on the backside 12 toward the outer peripheral edge 14 by a centrifugal force due to the rotation of the wafer w. The backside 12 of the wafer w is covered with the rinse liquid spread from the first position 101 and the second position 102.

The second position 102 is closer to the outer peripheral edge 14 of the wafer w than the first position 101 is. Therefore, the time required for the rinse liquid discharged from the second discharge nozzle 42 toward the second position 102 on the backside 12 to reach the outer peripheral edge 14 is shorter than the time required for the rinse liquid discharged from the first discharge nozzle 41 toward the first position 101 on the backside 12 to reach the outer peripheral edge 14. For this reason, the time for which a centrifugal force acts on the rinse liquid discharged toward the second position 102 is shorter than the time for which a centrifugal force acts on the rinse liquid discharged toward the first position 101. As a result, the flow velocity of the rinse liquid that reaches the outer peripheral edge 14 from the second position 102 on the wafer w is lower than the flow velocity of the rinse liquid that reaches the outer peripheral edge 14 from the first position 101. Due to such a low flow velocity, the rinse liquid that reaches the outer peripheral edge 14 from the second position 102 on the wafer w is not easily scattered from the outer peripheral edge 14 of the wafer w to its surroundings, and is spread from the outer peripheral edge 14 of the wafer w to an outer peripheral end surface 15 thereof due to surface tension.

After that, while the second discharge nozzle 42 is discharging the rinse liquid toward the second position 102, the controller 10 stops the supply of the adhesion liquid onto the front side 11 of the wafer w from the supply nozzle 30. That is, the discharge of the rinse liquid to the second position is stopped after the supply of the adhesion liquid is stopped. The controller 10 stops the discharge of the rinse liquid onto the backside 12 of the wafer w from the first discharge nozzle 41 and the second discharge nozzle 42. Alternatively, the supply of the adhesion liquid and the discharge of the rinse liquid may be simultaneously stopped.

With the above-described configuration, the backside 12 of the wafer w is covered with the rinse liquid, and thus adhesion of the adhesion liquid to the backside 12 of the wafer w can be reduced. In addition, even when the adhesion liquid adheres to the backside 12 of the wafer w, the adhesion liquid can be washed away by the rinse liquid discharged onto the backside 12 of the wafer w. In addition, the rinse liquid discharged to the second position 102 is spread from the outer peripheral edge 14 of the wafer w to the outer peripheral end surface 15 thereof, and thus the rinse liquid is spread over the outer peripheral end surface 15 of the wafer w. As a result, adhesion of the adhesion liquid to the outer peripheral end surface 15 is reduced. In addition, even when the adhesion liquid adheres to the outer peripheral end surface 15 of the wafer w, the adhesion liquid can be washed away by the rinse liquid that is spread over the outer peripheral end surface 15 of the wafer w. In this way, adhesion of the adhesion liquid to the backside 12 and the outer peripheral end surface 15 of the wafer w can be reduced. For example, even when the adhesion liquid scattered from the outer peripheral edge 14 of the wafer w to its surroundings hits the side surface of the cup 70, is splashed back from the side surface, and then comes around behind the backside 12 of the wafer w, adhesion of the adhesion liquid to the backside 12 of the wafer w can be reduced by the rinse liquid. In addition, even when the adhesion liquid drips from the outer peripheral edge 14 of the wafer w, adhesion of the adhesion liquid to the outer peripheral end surface 15 of the wafer w can be reduced by the rinse liquid.

While one embodiment has been described above, the specific configurations are not limited to those in the foregoing embodiment. In the following description, the same configurations as those in the foregoing description will be denoted by the same reference numerals as those in the foregoing description, and detailed description thereof will be omitted.

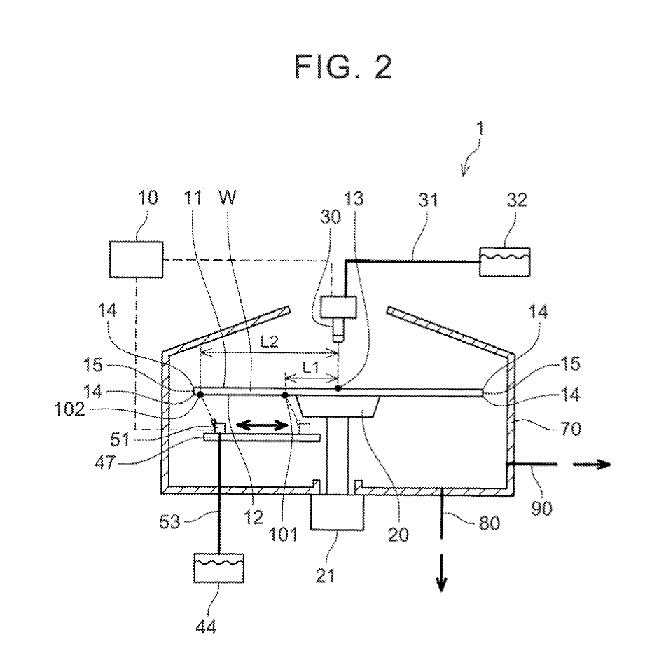

While the manufacturing apparatus 1 in the first embodiment includes the first discharge nozzle 41 and the second discharge nozzle 42, the configuration is not limited to this. In a second embodiment, as illustrated in FIG. 2, the manufacturing apparatus 1 may include a movable discharge nozzle 51 instead of the first discharge nozzle 41 and the second discharge nozzle 42. The movable discharge nozzle 51 and the supply nozzle 30 are connected to the controller 10. The controller 10 controls the operations of the movable discharge nozzle 51 and the supply nozzle 30.

The movable discharge nozzle 51 is connected to a supply line 53. The supply line 53 is connected to the rinse liquid supply source 44. The rinse liquid is delivered from the rinse liquid supply source 44 to the movable discharge nozzle 51 through the supply line 53. The movable discharge nozzle 51 moves back and forth between the first position 101 and the second position 102. The movable discharge nozzle 51 repeatedly moves back and forth between the first position 101 and the second position 102. The supply line 53 connected to the movable discharge nozzle 51 also moves back and forth together with the movable discharge nozzle 51. The movable discharge nozzle 51 discharges the rinse liquid onto the backside 12 of the wafer w while the wafer w is rotating in accordance with the rotation of the rotary holding table 20. The movable discharge nozzle 51 discharges the rinse liquid to the first position 101 and the second position 102. The movable discharge nozzle 51 keeps discharging the rinse liquid while moving back and forth between the first position 101 and the second position 102. The movable discharge nozzle 51 discharges the rinse liquid outward in the radial direction of the wafer w and obliquely upward from the wafer w rotational center side. The rinse liquid discharged onto the backside 12 of the wafer w is spread from each of the first position 101 and the second position 102 on the wafer w toward the outer peripheral edge 14 by a centrifugal force due to the rotation of the wafer w.

The controller 10 detects a position of the movable discharge nozzle 51 while the movable discharge nozzle 51 is moving back and forth between the first position 101 and the second position 102. The controller 10 controls the operation of the supply nozzle 30 based on the position of the movable discharge nozzle 51. More specifically, while the movable discharge nozzle 51 is discharging the rinse liquid toward the second position 102, the controller 10 stops the supply of the adhesion liquid onto the front side 11 of the wafer w from the supply nozzle 30. Next, the controller 10 stops the discharge of the rinse liquid onto the backside 12 of the wafer w from the movable discharge nozzle 51.

With the above-described configuration, the rinse liquid is spread over the backside 12 and the outer peripheral end surface 15 of the wafer w as described above, and thus adhesion of the adhesion liquid to the backside 12 and the outer peripheral end surface 15 of the wafer w is reduced. In addition, even when the adhesion liquid adheres to the backside 12 and the outer peripheral end surface 15 of the wafer w, the adhesion liquid can be washed away by the rinse liquid. In addition, using a single nozzle to discharge the rinse liquid onto the backside 12 of the wafer w can simplify the configuration on the backside side of the wafer w. In the second embodiment, the supply of the adhesion liquid onto the front side 11 of the wafer w from the supply nozzle 30 is stopped while the movable discharge nozzle 51 is discharging the rinse liquid toward the second position 102. However, the configuration is not limited to this. In another embodiment, the supply of the adhesion liquid onto the front side 11 of the wafer w from the supply nozzle 30 may be stopped while the movable discharge nozzle 51 is discharging the rinse liquid toward a position different from the second position 102.

In the foregoing embodiments, the wafer w is held at the backside 12. However, the configuration is not limited to this. In another embodiment, the wafer w may be held at the front side 11. For example, the front side 11 of the wafer w may be suctioned, so that the wafer w is held. Alternatively, the wafer w may be held at both the front side 11 and the backside 12.

While the example embodiments have been described above, these embodiments are just examples and not intended to limit the scope of claims. The technology described in the scope of claims includes various changes and modifications made to the example embodiments described above. The technical elements described in the specification and the drawings exhibit technical utility independently or in various combinations and are not limited to the combinations described in claims at the time of filing of the present application. In addition, the technologies described in the specification and the drawings can simultaneously achieve a plurality of purposes, and have technical utility as long as one of these purposes is accomplished.

An example of the technical elements in the specification will be described below. Further, the technical elements described below are technical elements independent from each other, and exhibit technical utility independently or in various combinations.

A manufacturing apparatus for a semiconductor device may include a first discharge nozzle configured to discharge a rinse liquid toward a first position and a second discharge nozzle configured to discharge the rinse liquid toward a second position.

With this configuration, the rinse liquid can be simultaneously discharged to the first position and the second position because the first discharge nozzle and the second discharge nozzle are provided. Adhesion of an adhesion liquid to a backside and an outer peripheral end surface of a wafer is more reliably reduced.

A manufacturing apparatus for a semiconductor device may include a movable discharge nozzle configured to move back and forth between a first position and a second position to discharge a rinse liquid toward the first position and the second position. While the movable discharge nozzle is discharging the rinse liquid toward the second position, the supply of an adhesion liquid from a supply nozzle may be stopped.

With this configuration, the configuration in which a single nozzle discharges a rinse liquid onto a backside of a wafer may be employed. In this way, the configuration on the backside side of the wafer can be simplified.

What is claimed is:

1. A manufacturing apparatus for a semiconductor device, the manufacturing apparatus comprising:
a rotary holding table configured to rotate a wafer having a disk-shape while holding a central portion of at least one of a front side and a backside of the wafer;
a supply nozzle configured to supply an adhesion liquid onto the front side of the wafer while the wafer is rotating, the adhesion liquid being a liquid to be caused to adhere to the front side of the wafer; and
at least one discharge nozzle configured to discharge a rinse liquid toward a first position and a second position on the backside of the wafer while the wafer is rotating, the second position being closer to an outer peripheral edge of the wafer than the first position is in a direction from the outer peripheral edge of the wafer toward a rotational center of the wafer.

2. The manufacturing apparatus according to claim 1, wherein the at least one discharge nozzle includes a first discharge nozzle configured to discharge the rinse liquid toward the first position and a second discharge nozzle configured to discharge the rinse liquid toward the second position.

3. The manufacturing apparatus according to claim 1, wherein the at least one discharge nozzle is a movable discharge nozzle configured to be movable between the first position and the second position, the movable discharge nozzle configured to discharge the rinse liquid toward the first position and the second position.

4. The manufacturing apparatus according to claim 1, wherein:
a direction in which the at least one discharge nozzle discharges the rinse liquid includes a directional component from the rotational center of the wafer to the outer peripheral edge of the wafer; and
the at least one discharge nozzle is configured to obliquely discharge the rinse liquid from a position on a side of the backside of the wafer.

5. A method of manufacturing a semiconductor device, the method comprising:
supplying an adhesion liquid onto a front side of a wafer having a disk-shape while the wafer is rotating, the adhesion liquid being a liquid to be caused to adhere to the front side of the wafer; and
discharging a rinse liquid toward a first position and a second position on a backside of the wafer while the wafer is rotating, the second position being closer to an outer peripheral edge of the wafer than the first position is in a direction from the outer peripheral edge of the wafer toward a rotational center of the wafer.

6. The method according to claim 5, further comprising,
stopping discharge of the rinse liquid toward the second position after stopping supply of the adhesion liquid.
